(19) United States
(12) Patent Application Publication
(10) Pub. No.: US 2024/0357855 A1
(43) Pub. Date: Oct. 24, 2024

(54) QUANTUM DOT LIGHT EMITTING DIODE, MANUFACTURING METHOD THEREOF AND DISPLAY PANEL

(71) Applicants: Beijing BOE Technology Development Co., Ltd., Beijing (CN); BOE TECHNOLOGY GROUP CO., LTD., Beijing (CN)

(72) Inventor: Jingwen FENG, Beijing (CN)

(21) Appl. No.: 18/028,558

(22) PCT Filed: Apr. 24, 2022
(86) PCT No.: PCT/CN2022/088688

§ 371 Date: Mar. 26, 2023

(51) Int. Cl. H10K 50/852; H10K 50/115; H10K 50/818; H10K 50/828

(52) U.S. Cl. CPC H10K 50/852; H10K 50/115; H10K 50/818; H10K 50/828

(57) ABSTRACT

The present disclosure provides a quantum dot light emitting diode, includes a first electrode, a second electrode and a quantum dot light emitting layer between the first electrode and the second electrode, where one of the first electrode and the second electrode is a reflective electrode, and the other is a transmissive electrode or a transflective electrode; at least one optical adjustment layer is arranged between the first electrode and the second electrode, each optical adjustment layer forms a microcavity structure with the reflective electrode, and light extraction efficiency P of the quantum dot light emitting diode satisfies 25%≤P≤98%. An embodiment of the present disclosure further provides a method of manufacturing a quantum dot light emitting diode and a display panel.

### TECHNICAL FIELD

The present disclosure relates to the field of display, and particularly to a quantum dot light emitting diode, a manufacturing method thereof and a display panel.

### BACKGROUND

A Quantum Dot Light Emitting diode (QLED) generally includes a cathode, an anode, and a quantum dot light emitting layer having a plurality of quantum dots of nanocrystals, and the quantum dot light emitting layer is sandwiched between the cathode and the anode. By applying an electric field to the quantum dot light emitting diode, electrons and holes are moved into the quantum dot light emitting layer, and the electrons and holes in the light emitting quantum dot light emitting layer are trapped in the quantum dots and recombined, to emit photons. Compared with an organic light emitting diode, the emission spectrum of the quantum dot light emitting diode is narrower. However, the light extraction efficiency of the conventional quantum dot light emitting diode is generally low, and it is difficult to further improve the emission intensity.

### SUMMARY

The present disclosure aims to solve at least one technical problem in the prior art and provides a quantum dot light emitting diode, a manufacturing method thereof and a display panel.

In a first aspect, an embodiment of the present disclosure provides a quantum dot light emitting diode, including a first electrode, a second electrode and a quantum dot light emitting layer between the first electrode and the second electrode, where one of the first electrode and the second electrode is a reflective electrode, and the other of the first electrode and the second electrode is a transmissive electrode or a transflective electrode; and
at least one optical adjustment layer is between the first electrode and the second electrode, each of the at least one optical adjustment layer is configured to form a microcavity structure with the reflective electrode, such that light extraction efficiency P of the quantum dot light emitting diode satisfies 25%≤P≤98%.

In some embodiments, a transmittance Q of the optical adjustment layer satisfies 70%≤Q<100%; and
a reflectivity R of the optical adjustment layer satisfies 0<R≤30%.

In some embodiments, a thickness of the optical adjustment layer is in a range of 1 nm to 35 nm.

In some embodiments, a refractive index of the optical adjustment layer is in a range of 0.1 to 0.3.

In some embodiments, a material of the optical adjustment layer includes a semiconductor material or a metal material.

In some embodiments, the material of the optical adjustment layer includes the metal material, and the optical adjustment layer is not in direct contact with the quantum dot light emitting diode.

In some embodiments, at least one functional dielectric layer is between the optical adjustment layer and the reflective electrode, and satisfies:

$$\vert {ϕ}_{1} \vert + \vert {ϕ}_{2} \vert + \frac{2 π}{λ} {\sum }_{i = 1}^{k} 2 {n}_{i} {d}_{i} = {m}_{1} * 2 π$$

where Φ₁ represents a phase shift generated by reflection of light on the reflective electrode, Φ₂ represents a phase shift generated by reflection of light on the optical adjustment layer, k represents the number of the at least one functional dielectric layer between the optical adjustment layer and the reflective electrode, nᵢ and dᵢ represent a refractive index and a thickness of an i^{th} functional dielectric layer close to the reflective electrode, respectively, m₁ is a preset positive integer, λ represents an emission peak wavelength of the quantum dot light emitting layer, and i is an integer and 1≤i≤k.

In some embodiments, one of the first electrode and the second electrode is the reflective electrode and the other of the first electrode and the second electrode is the transflective electrode;
the functional dielectric layer between the transflective electrode and the reflective electrode satisfies:

$$\vert {ϕ}_{1} \vert + \vert {ϕ}_{3} \vert + \frac{2 π}{λ} {\sum }_{j = 1}^{s} 2 {n}_{j} {d}_{j} = {m}_{2} * 2 π$$

where Φ₃ represents a phase shift generated by reflection of light on the transflective electrode, s represents the number of the at least one functional dielectric layer between the transflective electrode and the reflective electrode, nⱼ and dⱼ represent a refractive index and a thickness of an j^{th} functional dielectric layer close to the reflective electrode, respectively, m₂ is a preset positive integer and m₂>m₁, and j is an integer and 1≤j≤s.

In some embodiments, one of the first electrode and the second electrode serves as a cathode of the quantum dot light emitting diode, and the other of the first electrode and the second electrode serves as an anode of the quantum dot light emitting diode:
an electron transport layer is between the cathode and the quantum dot light emitting layer; and
a hole injection layer and a hole transport layer are between the anode and the quantum dot light emitting layer.

In some embodiments, the at least one optical adjustment layer includes a first optical adjustment layer, a material of the first optical adjustment layer includes a semiconductor material; and
the first optical adjustment layer is between the anode and the quantum dot light emitting layer, and an absolute value of a difference between a HOMO energy level of the first optical adjustment layer and a HOMO energy level of the hole transport layer is greater than 1 eV.

In some embodiments, the at least one optical adjustment layer includes a second optical adjustment layer, a material of the second optical adjustment layer includes a semiconductor material; and
the second optical adjustment layer is between the cathode and the quantum dot light emitting layer, an absolute value of a difference between a HOMO energy level of the second optical adjustment layer and a HOMO energy level of the hole transport layer is less than 0.5 eV, and an absolute value of a difference between a LUMO energy level of the second optical adjustment layer and a LUMO energy level of the hole transport layer is greater than 1 eV.

In some embodiments, at least a part of a surface of the optical adjustment layer away from the quantum dot light emitting layer is convex or concave:
and/or at least a part of a surface of the optical adjustment layer close to the quantum dot light emitting layer is convex or concave.

In some embodiments, the quantum dot light emitting diode further includes a base substrate, the first electrode is on the base substrate, and the second electrode is on a side of the first electrode away from the base substrate; and
the first electrode is the reflective electrode, and the second electrode is the transflective electrode;
or, the first electrode is the transmissive electrode, and the second electrode is the reflective electrode.

In some embodiments, the reflective electrode serves as an anode of the quantum dot light emitting diode, and a material of the reflective electrode includes a metal material; and
a metal oxide electrode adjacent to the reflective electrode is on a side of the reflective electrode close to the quantum dot light emitting layer.

In a second aspect, an embodiment of the present disclosure further provides a display panel, including the quantum dot light emitting diode as provided in the above first aspect.

The display panel includes a first quantum dot light emitting diode emitting blue light and a second quantum dot light emitting diode emitting light of other colors, where at least the first quantum dot light emitting diode is the quantum dot light emitting diode; and
a number of the microcavity structures in the first quantum dot light emitting diode is greater than a number of the microcavity structures in the second quantum dot light emitting diode.

In a third aspect, an embodiment of the present disclosure further provides a method of manufacturing the quantum dot light emitting diode in the first aspect, including:
forming the first electrode, the second electrode, the quantum dot light emitting layer and the at least one optical adjustment layer, where the quantum dot light emitting layer is between the first electrode and the second electrode, one of the first electrode and the second electrode is a reflective electrode, and the other of the first electrode and the second electrode is a transmissive electrode or a transflective electrode: each of the at least one optical adjustment layer is configured to form a microcavity structure with the reflective electrode, such that the light extraction efficiency P of the quantum dot light emitting diode satisfies 25%≤P≤98%.

In some embodiments, the optical adjustment layer is formed through an evaporation process, a spin coating process, or a printing process.

### BRIEF DESCRIPTION OF DRAWINGS

FIG. 1 is a schematic cross-sectional view of a quantum dot light emitting diode according to an embodiment of the present disclosure;

FIG. 2 is a schematic cross-sectional view of a quantum dot light emitting diode without an optical adjustment layer according to an embodiment of the present disclosure:

FIG. 3 is a schematic cross-sectional view of the quantum dot light emitting diode shown in FIG. 2 with an optical adjustment layer arranged between a hole transport layer and a quantum dot light emitting layer in the quantum dot light emitting diode;

FIG. 4 is a diagram illustrating simulated emission spectra of the quantum dot light emitting diodes shown in FIGS. 2 and 3;

FIG. 5 is a diagram illustrating simulated emission spectra of the quantum dot light emitting diodes shown in FIG. 3 with the optical adjustment layers of different thicknesses;

FIG. 6 is a diagram illustrating simulated emission spectra of the quantum dot light emitting diodes shown in FIG. 3 with the optical adjustment layers of different refractive indexes;

FIGS. 7 to 10 are schematic cross-sectional views of quantum dot light emitting diodes with the optical adjustment layers located at different positions in the quantum dot light emitting diodes according to embodiments of the present disclosure, respectively;

FIG. 11 is a diagram illustrating simulated emission spectra of the quantum dot light emitting diodes shown in FIGS. 2 and 7 to 10;

FIG. 12 is a graph of luminance versus current efficiency of the quantum dot light emitting diodes shown in FIGS. 2 and 10;

FIG. 13 is a graph of luminance versus external quantum efficiency of the quantum dot light emitting diodes shown in FIGS. 2 and 10;

FIG. 14 is a schematic cross-sectional view of another quantum dot light emitting diode according to an embodiment of the present disclosure; and

FIG. 15 is a flowchart of a method of manufacturing a quantum dot light emitting diode according to an embodiment of the present disclosure.

### DETAIL DESCRIPTION OF EMBODIMENTS

In order to enable one of ordinary skill in the art to better understand the technical solutions of the present disclosure, a quantum dot light emitting diode, a manufacturing method thereof, and a display panel provided by the present disclosure will be described in detail below with reference to the accompanying drawings.

As used herein, the term “about” or “approximately” means that the stated value and a value within an acceptable range of deviation for the particular value are included, where the acceptable range of deviation is determined by one of ordinary skill in the art in view of the measurement in question and the error associated with the measurement of the particular quantity (i.e., the limitations of the measurement system). For example, the term “about” may mean that a difference with respect to the stated value is within one or more standard deviations, or within +30%, +20%, +10%, +5% of the stated value.

Hereinafter, a Highest Occupied Molecular Orbital (“HOMO”) energy level and a Lowest Unoccupied Molecular Orbital (LUMO) energy level each represents an absolute value from vacuum. Further, when the HOMO or LUMO energy level is referred to as ‘deep’, ‘high’, or ‘large’, the HOMO or LUMO energy level has a great absolute value with respect to ‘0 eV’, i.e., a vacuum level, and when the HOMO or LUMO energy level is referred to as ‘shallow’, ‘low’, or ‘small’, the HOMO or LUMO energy level has a low absolute value from ‘0 eV’, i.e., the vacuum level.

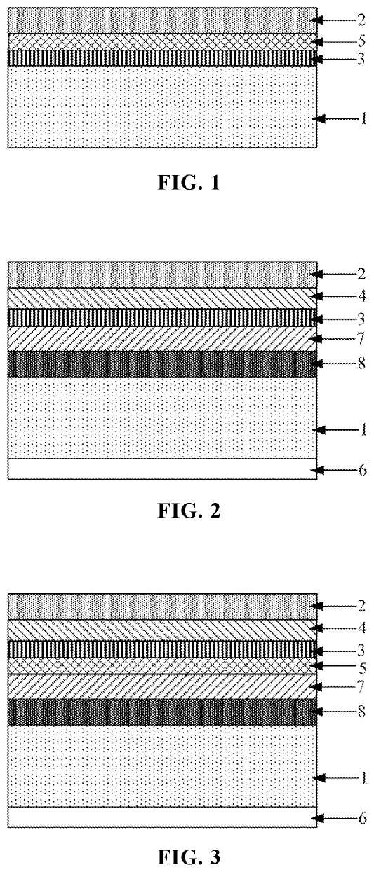

FIG. 1 is a schematic cross-sectional view of a quantum dot light emitting diode according to an embodiment of the present disclosure. As shown in FIG. 1, the quantum dot light emitting diode includes a first electrode 1, a second electrode 2 and a quantum dot light emitting layer 3 arranged between the first electrode 1 and the second electrode 2, where one of the first electrode 1 and the second electrode 2 is a reflective electrode, and the other one of the first electrode 1 and the second electrode 2 is a transmissive electrode or a transflective electrode. At least one optical adjustment layer 5 is arranged between the first electrode 1 and the second electrode 2. The optical adjustment layer 5 is configured to form a microcavity structure with the reflective electrode, so that the light extraction efficiency P of the quantum dot light emitting diode satisfies 25%≤P≤98%.

One of the first electrode 1 and the second electrode 2 serves as an anode of the quantum dot light emitting diode, and the other of the first electrode 1 and the second electrode 2 serves as a cathode of the quantum dot light emitting diode. With different voltages applied between the first electrode 1 and the second electrode 2 to form an electric field, the quantum dot light emitting layer 3 can be driven to emit light.

In the embodiment of the present disclosure, the microcavity structure can effectively improve the light extraction efficiency of the quantum dot light emitting diode. The light extraction efficiency of the quantum dot light emitting diode is equal to a ratio of an actual light output of the quantum dot light emitting diode (expressed by an emission intensity of the quantum dot light emitting diode in the present disclosure) to a light output of the quantum dot light emitting layer 3 (expressed by an emission intensity of the quantum dot light emitting layer 3 in the present disclosure).

In the technical solution of the present disclosure, at least one optical adjustment layer 5 is arranged between the first electrode 1 and the second electrode 2, and the optical adjustment layer 5 forms a microcavity structure with the reflective electrode, so that the light extraction efficiency of the quantum dot light emitting diode can be improved based on the microcavity effect of this microcavity structure, which is favorable to improving the emission intensity of the quantum dot light emitting diode. In the embodiment of the present disclosure, the optical adjustment layer 5 is specifically a functional layer with transflective characteristics.

Where the light emitting region of the device is located in a resonant cavity formed by a reflective film (i.e., the reflective electrode in the present disclosure) and a transflective film (i.e., the optical adjustment layer 5 in the present disclosure), and a cavity length and a light wavelength are in a same order of magnitude, light with a specific wavelength is selected and enhanced, and the spectrum is narrowed, which is a microcavity effect.

It should be noted that, the case shown in FIG. 1 only exemplarily illustrates a case where one optical adjustment layer 5 is arranged between the first electrode 1 and the second electrode 2, and this case is only exemplary, and does not limit the technical solution of the present disclosure.

In addition, in order to enable the optical adjustment layer 5 and the reflective electrode to form a microcavity structure, it is required to ensure that at least one functional dielectric layer exists between the optical adjustment layer 5 and the reflective electrode. That is, the optical adjustment layer 5 is not adjacent to the reflective electrode. In the case shown in FIG. 1, the first electrode 1 serves as a reflective electrode, the second electrode 2 serves as a transflective electrode, and in order to make the optical adjustment layer 5 be not adjacent to the reflective electrode (the first electrode 1), it is required to arrange the optical adjustment layer 5 between the quantum dot light emitting layer 3 and the second electrode 2. In this case, a functional dielectric layer, i.e., the quantum dot light emitting layer 3, exists between the optical adjustment layer 5 and the reflective electrode.

Alternatively, in the case shown in FIG. 1, any other optical adjustment layer may be further arranged between the optical adjustment layer 5 and the second electrode 2/quantum dot light emitting layer 3, so that the number of the optical adjustment layers 5 located between the first electrode 1 and the second electrode 2 is greater than or equal to 2, and each optical adjustment layer 5 and the reflective electrode may form a microcavity structure capable of improving the light extraction efficiency of the quantum dot light emitting diode. No corresponding figures are given in this case.

In some embodiments, at least one functional dielectric layer exists between the optical adjustment layer 5 and the reflective electrode, and satisfies:

$$\vert {ϕ}_{1} \vert + \vert {ϕ}_{2} \vert + \frac{2 π}{λ} {\sum }_{i = 1}^{k} 2 {n}_{i} {d}_{i} = {m}_{1} * 2 π , \qquad formula ( 1 )$$

where Φ₁ represents a phase shift generated by the reflection of light on the reflective electrode, Φ₂ represents a phase shift generated by the reflection of light on the optical adjustment layer 5, k represents the number of the functional dielectric layers between the optical adjustment layer 5 and the reflective electrode, nᵢ and dᵢ represent a refractive index and a thickness of an i^{th} functional dielectric layer close to the reflective electrode, respectively, m₁ is a preset positive integer (m₁ represents a modulus of a microcavity formed by the optical adjustment layer 5 and the reflective electrode), λ represents an emission peak wavelength of the quantum dot light emitting layer 3, and i is an integer and 1≤i≤k.

In the case shown in FIG. 1, only one functional dielectric layer, i.e., the quantum dot light emitting layer 3, exists between the optical adjustment layer 5 and the reflective electrode. That is, k takes a value of 1.

By satisfying the formula (1), a microcavity structure formed by the optical adjustment layer 5 and the reflective electrode can achieve a strong microcavity effect.

In some embodiments, one of the first electrode 1 and the second electrode 2 is a reflective electrode, and the other of the first electrode 1 and the second electrode 2 is a transflective electrode (for example, in FIG. 1, the first electrode 1 is a reflective electrode, and the second electrode 2 is a transflective electrode), and the functional dielectric layer located between the transflective electrode and the reflective electrode satisfies:

$$\vert {ϕ}_{1} \vert + \vert {ϕ}_{3} \vert + \frac{2 π}{λ} {\sum }_{j = 1}^{s} 2 {n}_{j} {d}_{j} = {m}_{2} * 2 π , \qquad formula ( 1 )$$

where Φ₃ represents a phase shift generated by the reflection of light on the transflective electrode, s represents the number of the functional dielectric layers between the transflective electrode and the reflective electrode, nⱼ and dⱼ represent a refractive index and a thickness of an j^{th} functional dielectric layer close to the reflective electrode, respectively, m₂ is a preset positive integer (m₂ represents a modulus of a microcavity formed by the transflective electrode and the reflective electrode) and m₂>m₁, and j is an integer and 1≤j≤s.

That is to say, not only the optical adjustment layer 5 and the reflective electrode can form a microcavity structure for improving the light output of the quantum dot light emitting diode, but also the transflective electrode and the reflective electrode can form a microcavity structure for improving the light output of the quantum dot light emitting diode. Then, in the case shown in FIG. 1, there are two microcavity structures capable of improving the light output of the quantum dot light emitting diode, which is favorable to further improving the light extraction efficiency and the emission intensity of the quantum dot light emitting diode.

In the case shown in FIG. 1, two functional dielectric layers, i.e., the quantum dot light emitting layer 3 and the optical adjustment layer 5, exist between the transflective electrode (the second electrode 2) and the reflective electrode (the first electrode 1). That is, s takes a value of 2.

By satisfying the formula (2), a microcavity structure formed by the transflective electrode and the reflective electrode can achieve a strong microcavity effect.

In the embodiment of the present disclosure, specific values of m1 and m2 may be set according to actual needs. For example, where only one optical adjustment layer 5 is provided, m1=1 and m2=2, or m1=1 and m2=3, or m1=2 and m2=3. Where at least two optical adjustment layers 5 are provided, the modulus values corresponding to the microcavities formed by the optical adjustment layers 5 and the reflective electrode are all different, and the modulus of the microcavity formed by the transflective electrode and the reflective electrode is greater than the modulus corresponding to the microcavity formed by any one optical adjustment layer 5 and the reflective electrode. In practical applications, in order to prevent a thickness of the quantum dot light emitting diode from being excessive, the modulus of the microcavity formed by the optical adjustment layer 5/the transflective electrode and the reflective electrode is generally designed to be lower.

In some embodiments, a transmittance of the optical adjustment layer 5 is Q, and a reflectance R of the optical adjustment layer 5 is 1-Q, where Q and R satisfy 70%≤Q<100% and 0<R≤30%, respectively.

In some embodiments, the thickness of the optical adjustment layer 5 is in a range of 1 nm to 35 nm. In the expression of the range of A to B in the present disclosure, the defined range includes both endpoints A and B.

In some embodiments, a refractive index of the optical adjustment layer 5 is in a range of 0.1 to 0.3.

In some embodiments, a material of the optical adjustment layer 5 includes a semiconductor material or a metal material (e.g., gold, silver, copper, aluminum, magnesium, lithium, etc.).

Further optionally, where the optical adjustment layer 5 is made of a metal material, the optical adjustment layer 5 is not in direct contact with the quantum dot light emitting layer 3, so that it is prevent from occurring that the quantum dots in the quantum dot light emitting layer 3 quench, so that the emission intensity of the quantum dot light emitting layer 3 is reduced, which is not favorable to improving the light output of the quantum dot light emitting diode. In addition, where the material of the optical adjustment layer 5 is a metal material, a thickness of the optical adjustment layer 5 is in a range of 1 nm to 10 nm, to ensure that the transmittance Q satisfies 70%≤Q<100%.

It should be noted that, in some cases, even though the optical adjustment layer 5 made of a metal material is arranged adjacent to the quantum dot light emitting layer 3, so that the light output of the quantum dot light emitting layer 3 may be reduced, the microcavity effect is formed due to the presence of the optical adjustment layer 5, compared with a quantum dot light emitting diode without the optical adjustment layer 5, the overall emission efficiency of the quantum dot light emitting diode can be improved to a certain degree. See the examples below for details.

Where the material of the optical adjustment layer 5 is a semiconductor material, a position, where the optical adjustment layer 5 is arranged, is not limited in principle.

The following will continue to describe the technical solutions of the present disclosure in detail in connection with some examples.

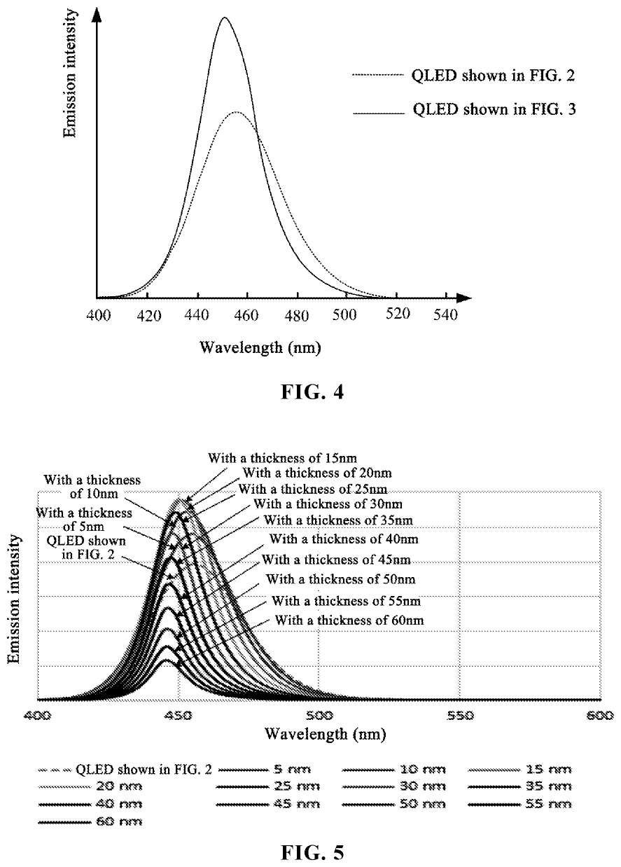

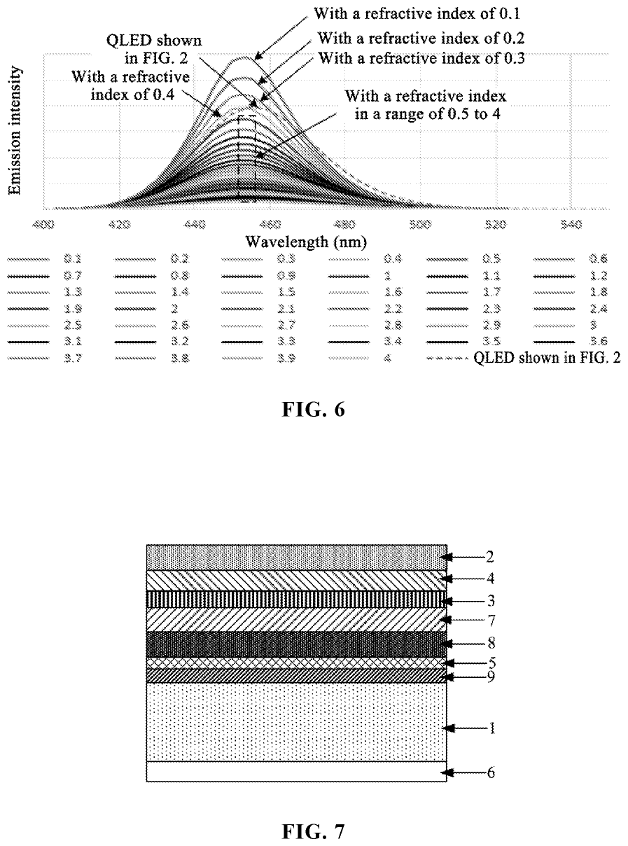

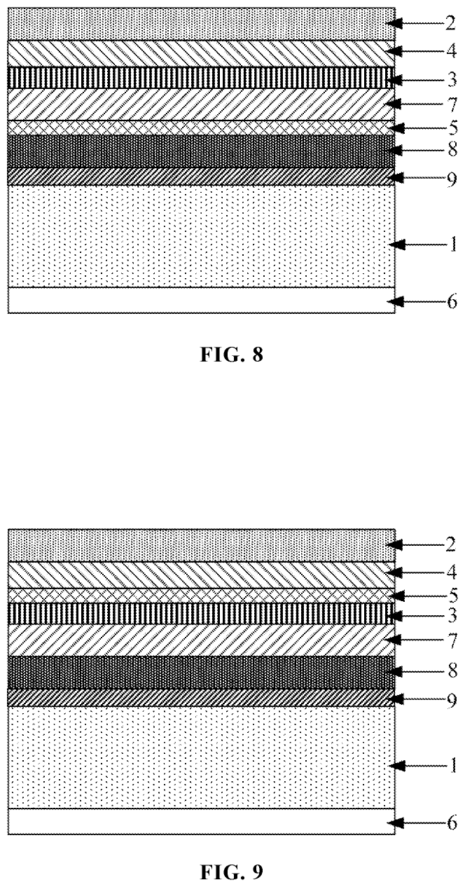

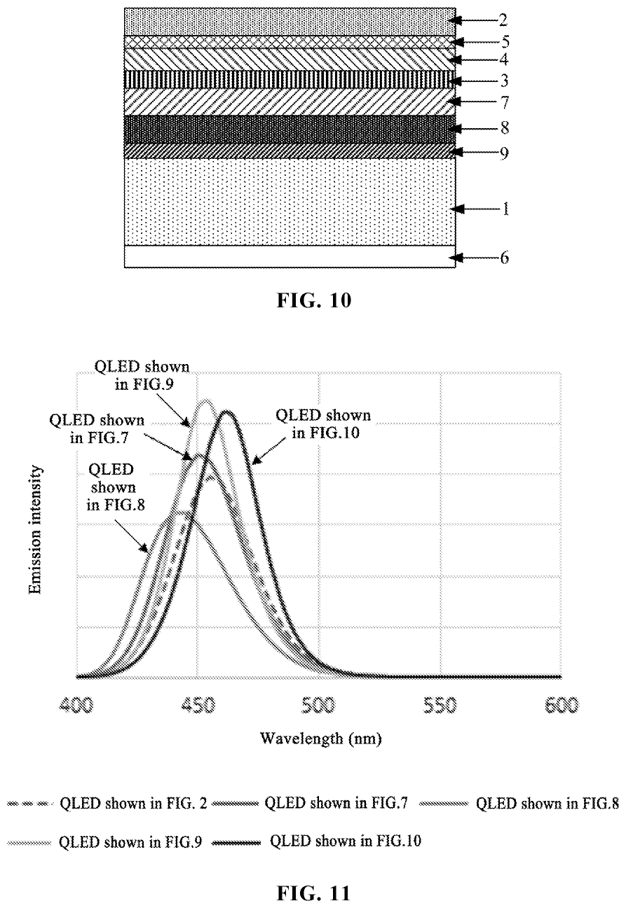

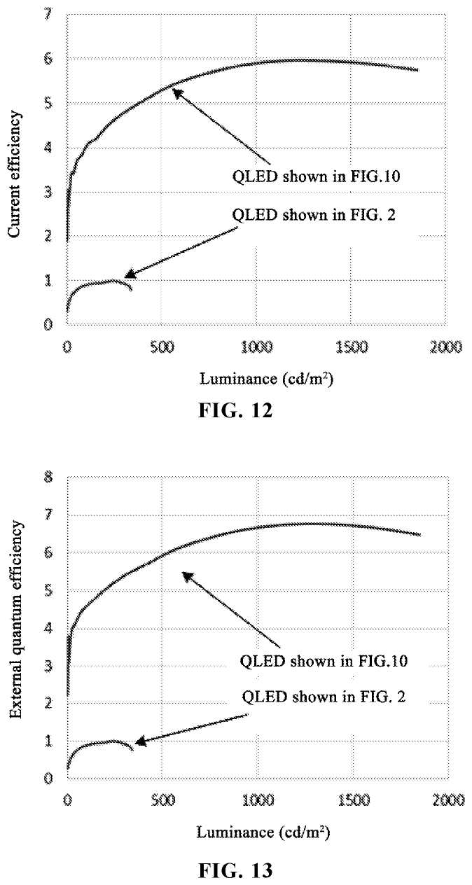

FIG. 2 is a schematic cross-sectional view of a quantum dot light emitting diode without an optical adjustment layer according to an embodiment of the present disclosure. FIG. 3 is a schematic cross-sectional view of the quantum dot light emitting diode shown in FIG. 2 with an optical adjustment layer arranged between a hole transport layer 7 and a quantum dot light emitting layer 3 in the quantum dot light emitting diode. As shown in FIGS. 2 and 3, in some embodiments, in order to improve the number of carriers (including electrons and holes) injected into the quantum dot light emitting layer 3, an Electron Transport Layer 4 (ETL) is arranged between the cathode and the quantum dot light emitting layer 3, and a Hole Injection Layer 8 (HIL) and a Hole Transport Layer 7 (HTL) are arranged between the anode and the quantum dot light emitting layer 3.

In some embodiments, the quantum dot light emitting diode further includes a base substrate 6, and the second electrode 2 is located on a side of the first electrode 1 away from the base substrate 6.

In the case shown in FIGS. 2 and 3, it is taken as an example that the first electrode 1 serves as an anode, the second electrode 2 serves as a cathode, the first electrode 1 is a reflective electrode, and the second electrode 2 is a transflective electrode or a transparent electrode. It this case, the quantum dot light emitting diode is a top emission type quantum dot light emitting diode. When the top emission type quantum dot light emitting diode is applied to a display panel, since an array of Thin Film Transistors (TFTs) for driving the quantum dot light emitting diodes are located on a non-light outgoing side of the quantum dot light emitting diodes, so the array of thin film transistors will not shield light output from the quantum dot light emitting diodes, therefore light outgoing area of the light quantum dot light emitting diodes can be designed relatively large, which is favorable to improving the pixel aperture ratio.

In some embodiments, the material of the reflective electrode includes a metal material. In order to realize work function matching (which may also be regarded as fermi level matching), a metal oxide electrode 9 adjacent to the reflective electrode made of a metal material is arranged on a side of the reflective electrode close to the quantum dot light emitting layer 3, and the material of the metal oxide electrode 9 is a transparent and conductive metal oxide material.

Referring to FIGS. 2 and 3, the material of the first electrode 1 (reflective electrode) includes a metal material having a high work function, including but not limited to at least one of nickel, platinum, vanadium, chromium, copper, zinc, and gold. A thickness of the first electrode 1 may be designed to be relatively thick, in order to achieve the total reflection effect as much as possible (reflectivity of 100% or close to 100%) and to ensure good conductivity. Alternatively, the thickness of the first electrode 1 as a reflective electrode is in a range of 70 nm to 150 nm, for example, 100 nm.

A material of the metal oxide electrode 9 includes, but is not limited to, a metal oxide, and may specifically include at least one of zinc oxide (ZnO), indium oxide (InO), tin oxide (SnO), Indium Tin Oxide (ITO), Indium Zinc Oxide (IZO), or fluorine-doped tin oxide (FTO). The metal oxide electrode 9 mainly functions as a work function matching, and its thickness may be designed to be relatively thin. Alternatively, the metal oxide electrode 9 has a thickness in a range of 5 nm to 12 nm, for example, 8 nm.

A material of the hole injection layer 8 includes, but is not limited to, poly(3,4-ethylenedioxythiophene)-poly(styrene sulfonate) (PEDOT:PSS), polythiophene, polyaniline, polypyrrole, or copper phthalocyanine.

A material of the hole transport layer 7 includes, but is not limited to, p-type polymer materials and various p-type low molecular weight materials, for example, polythiophene, polyaniline, polypyrrole, or a mixture having poly-(3,4-ethylenedioxy thiophene)-poly(styrenesulfonate), 4,4′-cyclohexylidenebis[N,N-bis(4-methylphenyl) aniline] (TAPC) or 4,4′,4″-tris(N-carbazolyl)-triphenylamine (TCTA), N,N′-bis-(1-naphthyl)-N,N′-diphenylbenzidine (NPB).

Thicknesses of the hole injection layer 8 and the hole transport layer 7 are set according to a desired hole transport rate. Optionally, the thickness of the hole injection layer 8 is in a range of 20 nm to 30 nm, for example, 24.5 nm; and the thickness of the hole transport layer 7 is in a range of 20 nm to 30 nm, for example, 26.8 nm.

The material of the quantum dot light emitting layer 3 includes, but is not limited to, cadmium-free (Cd-free) quantum dot material or blue light cadmium-containing quantum dot material; where the cadmium-free quantum dot material may be indium phosphide (InP) quantum dots or InP-derived core-shell structure quantum dots, such as InP/ZnSe/ZnS, InP/ZnSeS/ZnS; and the blue light cadmium-containing quantum dot material may be CdS/ZnSe/ZnS, CdSe/ZnSe/ZnS, or CdSInS/ZnSe/ZnS. Alternatively, other quantum dots, such as GaP/ZnSe, CsPbBr₃/ZnS, or the like, may be employed as the material of the quantum dot light emitting layer 3. Optionally, the thickness of the quantum dot light emitting layer 3 is in a range of 10 nm to 20 nm, for example, 14.1 nm. A material of the electron transport layer 4 includes, but is not limited to, at least one of zinc oxide (ZnO), magnesium zinc oxide (ZnMgO), aluminum zinc oxide (AZO), and magnesium aluminum zinc oxide. Optionally, the thickness of the electron transport layer 4 is in a range of 5 nm to 20 nm, for example, 8.9 nm.

The second electrode 2 may be a transparent electrode or a transflective electrode. Where the second electrode 2 is a transparent electrode, the second electrode 2 may be made of a conductive metal oxide material, and specifically may include at least one of zinc oxide, indium oxide, tin oxide, indium tin oxide, and indium zinc oxide. In this case, in order to ensure the conductive effect of the second electrode 2, a thickness of the transparent electrode formed of the metal oxide material is greater than 30 nm, for example, 70 nm. Where the second electrode 2 is a transflective electrode, the second electrode 2 may be made of a metal material with a lower work function than that of the first electrode 1, including but not limited to at least one of aluminum, magnesium, calcium, sodium, potassium, titanium, indium, yttrium, lithium, gadolinium, silver, tin, lead, cesium, and barium. In this case, in order to ensure that the second electrode 2 has a certain conductivity and exhibits a transflective effect, a thickness of the second electrode 2 cannot be set too thick or too thin, and optionally, the thickness of the transflective electrode formed of a metal material is in a range of 1 nm to 15 nm, for example, 10 nm.

FIG. 4 is a diagram illustrating emission spectra of the quantum dot light emitting diodes shown in FIGS. 2 and 3. As shown in FIG. 4, in FIGS. 2 and 3, the thickness of the first electrode 1 (reflective electrode) is 100 nm, the thickness of the metal oxide electrode 9 is 8 nm, the thickness of the hole transport layer 7 is 24.5 nm, the thickness of the hole injection layer 8 is 26.8 nm, the thickness of the quantum dot light emitting layer 3 is 14.1 nm, the material of the quantum dot light emitting layer is a quantum dot material capable of emitting blue light, the thickness of the electron transport layer 4 is 8.9 nm, and the second electrode 2 is a transflective electrode and the thickness thereof is 10 nm. In FIG. 4, a simulation is performed with the material of the transflective dielectric shown in FIG. 3 being a semiconductor material (having a refractive index of about 0.2 and the thickness of the transflective dielectric being 10 nm.

As shown in the simulation result of FIG. 4, compared with the case in FIG. 2 where the optical adjustment layer 5 is not included, in the solution shown in FIG. 3 where the optical adjustment layer 5 is arranged between the hole transport layer 7 and the quantum dot light emitting layer 3, the emission intensity of the quantum dot light emitting diode can be effectively improved. Specifically, compared with the single microcavity structure shown in FIG. 2 (the microcavity structure is formed between the transflective electrode and the reflective electrode), in the dual microcavity structure shown in FIG. 4 (one microcavity structure is formed between the optical adjustment layer 5 and the reflective electrode, and the other microcavity structure is formed between the transflective electrode and the reflective electrode), the emission intensity thereof is improved by about 32%, and the half-peak width is narrowed from 39 nm before optimization to 27 nm. The narrow half-peak width means that the purer the color of light emitted by the quantum dot light emitting diode is, and when the quantum dot light emitting diode is applied to a display panel, the color gamut of the display panel is favorably improved.

It should be noted that, in the embodiment of the present disclosure, a quantum dot light emitting diode emitting blue light is simulated to verify that the light extraction efficiency of the quantum dot light emitting diode can be improved after the optical adjustment layer 5 is arranged, which case serves as only an example and does not limit the technical solution of the present disclosure. The technical solution of the present disclosure can also be applied to quantum dot light emitting diodes emitting other colors of light, such as a red light quantum dot diode emitting red light and a green light quantum dot diode emitting green light.

FIG. 5 is a diagram illustrating simulated emission spectra of the quantum dot light emitting diodes shown in FIG. 3 with the optical adjustment layers of different thicknesses. As shown in FIG. 5, on the premise that the optical adjustment layer 5 in FIG. 3 is made of a semiconductor material and has a refractive index of about 0.2, cases where the optical adjustment layers 5 have different thicknesses are simulated. It can be seen from the simulation result shown in FIG. 5 that where the thickness of the optical adjustment layer 5 in the quantum dot light emitting diode shown in FIG. 3 is in a range of 5 nm to 35 nm, the emission intensity of the quantum dot light emitting diode is improved compared with the emission intensity of the quantum dot light emitting diode shown in FIG. 2.

FIG. 6 is a diagram illustrating simulated emission spectra of the quantum dot light emitting diodes shown in FIG. 3 with the optical adjustment layers of different refractive indexes. As shown in FIG. 6, on the premise that the optical adjustment layer 5 in FIG. 3 is made of a semiconductor material and has a thickness of 10 nm, cases where the optical adjustment layers 5 have different refractive indexes are simulated. It can be seen from the simulation result shown in FIG. 6 that where the refractive index of the optical adjustment layer 5 in the quantum dot light emitting diode shown in FIG. 3 is in a range of 0.1 to 0.3, the emission intensity of the quantum dot light emitting diode is improved compared with the emission intensity of the quantum dot light emitting diode shown in FIG. 2.

Alternatively, based on the foregoing formula (1) and formula (2), in order to achieve a better microcavity effect when the optical adjustment layer 5 is added, the thicknesses and refractive indexes of other dielectric layers between the first electrode 1 and the second electrode 2 are required to be comprehensively considered.

The present disclosure further simulates a case that the optical adjustment layer 5 is made of a metal material and is located at other position. FIGS. 7 to 10 are schematic cross-sectional views of the quantum dot light emitting diodes with the optical adjustment layer 5 located at different positions in the quantum dot light emitting diodes according to embodiments of the present disclosure. As shown in FIGS. 7 to 10, in the case shown in FIG. 7, the optical adjustment layer 5 is located between the metal oxide electrode 9 and the hole injection layer 8: in the case shown in FIG. 8, the optical adjustment layer 5 is located between the hole injection layer 8 and the hole transport layer 7: in the case shown in FIG. 9, the optical adjustment layer 5 is located between the quantum dot light emitting layer 3 and the electron transport layer 4; and in the case shown in FIG. 10, the optical adjustment layer 5 is located between the electron transport layer 4 and the second electrode 2.

FIG. 11 is a diagram illustrating simulated emission spectra of the quantum dot light emitting diodes shown in FIGS. 2 and 7 to 10. As shown in FIG. 11, in FIGS. 7 to 10, the thickness of the first electrode 1 (reflective electrode) is 100 nm, the thickness of the metal oxide electrode 9 is 8 nm, the thickness of the hole transport layer 7 is 24.5 nm, the thickness of the hole injection layer 8 is 26.8 nm, the thickness of the quantum dot light emitting layer 3 is 14.1 nm, the thickness of the electron transport layer 4 is 8.9 nm, and the second electrode 2 is a transflective electrode and the thickness thereof is 10 nm. In FIGS. 7 to 10, the optical adjustment layer 5 is made of a metal material and has a thickness of 3 nm.

As can be seen from the simulation results shown in FIG. 11, compared to the case where the optical adjustment layer 5 is not included in FIG. 2, the optical adjustment layer 5 is arranged between the metal oxide electrode 9 and the hole injection layer 8 as shown in FIG. 7, the optical adjustment layer 5 is arranged between the quantum dot light emitting layer 3 and the electron transport layer 4 as shown in FIG. 9, and the optical adjustment layer 5 is arranged between the electron transport layer 4 and the second electrode 2 as shown in FIG. 10. All of these three solutions can effectively improve the emission intensity of the quantum dot light emitting diode.

FIG. 12 is a graph of luminance versus current efficiency of the quantum dot light emitting diodes shown in FIGS. 2 and 10. FIG. 13 is a graph of luminance versus external quantum efficiency of the quantum dot light emitting diodes shown in FIGS. 2 and 10. As shown in FIGS. 12 and 13, the current efficiency of the quantum dot light emitting diode with the optical adjustment layer 5 shown in FIG. 10 is about 2 times that of the quantum dot light emitting diode without the optical adjustment layer 5 shown in FIG. 2; and the external quantum efficiency (EQE) of the quantum dot light emitting diode with the optical adjustment layer 5 shown in FIG. 10 is about 7 times that of the quantum dot light emitting diode without the optical adjustment layer 5 shown in FIG. 2. That is, the quantum dot light emitting diode with the optical adjustment layer 5 shown in FIG. 10 has a higher emission intensity than that of the quantum dot light emitting diode without the optical adjustment layer 5 shown in FIG. 2, under a same voltage.

The external quantum efficiency of the quantum dot light emitting diode is as follows:

$${η}_{EQE} = γ \times {η}_{rc} \times {η}_{out}$$

where γ is an electron-hole equilibrium constant, η_{rc} is the emission efficiency of the quantum dot light emitting layer 3, and ηₒᵤₜ is the light extraction efficiency of the quantum dot light emitting diode.

It is measured by experiments in advance that the addition of the optical adjustment layer 5 will not greatly affect the electron-hole balance in the quantum dot light emitting diode, and the values of the electron-hole balance constant of the quantum dot light emitting diodes shown in FIGS. 2 and 10 are approximately equal. Meanwhile, since the quantum dot light emitting layers 3 made of the same material and having the same thickness are employed in FIGS. 2 and 10, respectively, the emission efficiencies of the quantum dot light emitting layers 3 in FIGS. 2 and 10 is equal. Therefore, the difference between external quantum efficiencies of the quantum dot light emitting diodes shown in FIGS. 2 and 10 is necessarily due to the difference between light extraction efficiencies of the quantum dot light emitting diodes shown in FIGS. 2 and 10. That is, compared with the single microcavity structure (a microcavity structure is formed between the transflective electrodes) shown in FIG. 2, the dual microcavity structure (one microcavity structure is formed between the optical adjustment layer 5 and the reflective electrode, and the other microcavity structure is formed between the transflective electrode and the reflective electrode) shown in FIG. 10 can effectively improve the light extraction efficiency of the quantum dot light emitting diode.

In addition, referring to FIGS. 2, 8 and 11 again, although the optical adjustment layer 5 is present in the solution shown in FIG. 8, an amount of improvement of the light extraction efficiency of the quantum dot light emitting diode by the microcavity structure formed by the optical adjustment layer 5 and the reflective electrode is less than an amount of decrease of the light extraction efficiency of the quantum dot light emitting diode due to the decrease of the microcavity effect between the transflective electrode and the reflective electrode after the optical adjustment layer 5 is added, so that the actual light extraction efficiency of the quantum dot light emitting diode is decreased. The reason why the microcavity effect between the transflective electrode and the reflective electrode is weakened after the optical adjustment layer 5 is added, is that an optical path between the transflective electrode and the reflective electrode is changed after the optical adjustment layer 5 is added, and the microcavity effect between the transflective electrode and the reflective electrode is weakened.

In the solutions shown in FIGS. 7 to 10, the microcavity effect between the transflective electrode and the reflective electrode is affected the same after the optical adjustment layer 5 is added. That is to say, in the solutions shown in FIGS. 7, 9, and 10, the amount of improvement of the light extraction efficiency of the quantum dot light emitting diode by the microcavity structure formed by the optical adjustment layer 5 and the reflective electrode is greater than the amount of decrease of the light extraction efficiency of the quantum dot light emitting diode due to the decrease of the microcavity effect between the transflective electrode and the reflective electrode after the optical adjustment layer 5 is added, so that the actual light extraction efficiency of the quantum dot light emitting diode is improved.

Alternatively, in some cases, it may happen that the optical path between the transflective electrode and the reflective electrode is changed after the optical adjustment layer 5 is added, and the microcavity effect between the transflective electrode and the reflective electrode is enhanced.

Referring to FIG. 11 again, the emission peak of the quantum dot light emitting diode shown in FIG. 2 is around 458 nm, the emission peak of the quantum dot light emitting diode shown in FIG. 7 is around 450 nm, the emission peak of the quantum dot light emitting diode shown in FIG. 9 is around 452 nm, and the emission peak of the quantum dot light emitting diode shown in FIG. 10 is around 465 nm. An emission peak position of the quantum dot light emitting diode shown in FIG. 2 is taken as a reference, the emission peak positions of the quantum dot light emitting diodes shown in FIGS. 7, 9 and 10 are shifted, and the shift amount is less than 10 nm. Taking the quantum dot in the quantum dot light emitting layer 3 being blue light quantum dot as an example, after adding the optical adjustment layer 5, the emission peak position of the quantum dot light emitting diode can be blue shifted to a certain degree. When this quantum dot light emitting diode is applied to a display panel, the color gamut of full-color display can be improved to a certain extent. In addition, as can be seen from FIG. 11, the emission half-peak widths of the quantum dot light emitting diodes shown in FIGS. 7, 9 and 10 are each narrowed, which is also favorable to improving the color gamut of full-color display.

It should be noted that, the simulation result shown in FIG. 11 does not indicate that the optical adjustment layer 5 in the present disclosure cannot be arranged between the hole injection layer 8 and the hole transport layer 7, but indicates that where the first electrode 1 is a reflective electrode and has a thickness of 100 nm, the metal oxide electrode 9 has a thickness of 8 nm, the hole transport layer 7 has a thickness of 24.5 nm, the hole injection layer 8 has a thickness of 26.8 nm, the quantum dot light emitting layer 3 has a thickness of 14.1 nm, the electron transport layer 4 has a thickness of 8.9 nm, and the second electrode 2 is a transflective electrode and has a thickness of 10 nm, if the optical adjustment layer 5 made of a metal material and having a thickness of 3 nm is arranged between the hole injection layer 8 and the hole transport layer 7, the emission intensity of the quantum dot light emitting diode cannot be improved. However, in practical applications, the emission intensity of the quantum dot light emitting diode can be improved by adjusting the thickness and/or refractive indexes of some dielectric layers (including but not limited to the hole injection layer 8, the hole transport layer 7, the optical adjustment layer 5, the quantum dot light emitting layer 3, and the electron transport layer 4) between the first electrode 1 and the second electrode 2 (for example, adjusting the thickness of the optical adjustment layer 5, adjusting the refractive index of the optical adjustment layer 5, adjusting the thickness of the hole transport layer 7, adjusting the refractive index of the hole transport layer 7, and the like), so that the emission intensity of the quantum dot light emitting diode can be improved after the optical adjustment layer 5 is placed between the hole injection layer 8 and the hole transport layer 7.

In the quantum dot light emitting diode in the related art, a problem of low emission efficiency of the quantum dot light emitting layer 3 may occur due to unbalance between carrier transmission rates. For example, a hole transport rate is significantly greater than an electron transport rate (generally referred to as a “majority-hole system”), or the electron transport rate is significantly greater than the hole transport rate (generally referred to as a “majority-electron system”).

In order to solve the problem of the “majority-hole system” in the related art, in the embodiment of the present disclosure, a semiconductor material having an electron transport rate greater than a hole transport rate may be selected to form the optical adjustment layer 5, and the optical adjustment layer 5 is arranged between the anode and the quantum dot light emitting layer 3, to also serve as a hole block layer. Specifically, in some embodiments, the at least one optical adjustment layer 5 includes a first optical adjustment layer 5, a material of the first optical adjustment layer 5 includes a semiconductor material. The first optical adjustment layer 5 is located between the anode and the quantum dot light emitting layer 3 (for example, in cases shown in FIGS. 3, 7, and 8), an absolute value of a difference between a HOMO energy level of the first optical adjustment layer 5 and a HOMO energy level of the hole transport layer 7 is greater than 1 eV, and the first optical adjustment layer 5 also serves as a hole block layer.

In order to solve the problem of the “majority-electron system” in the related art, in the embodiment of the present disclosure, a semiconductor material having a hole transport rate greater than an electron transport rate may be selected to form the optical adjustment layer 5, and the optical adjustment layer 5 is arranged between the cathode and the quantum dot light emitting layer 3, to also serve as an electron block layer. Specifically, in some embodiments, the at least one optical adjustment layer 5 includes a second optical adjustment layer 5, and a material of the second optical adjustment layer 5 includes a semiconductor material. The second optical adjustment layer 5 is located between the cathode and the quantum dot light emitting layer 3 (for example, in the cases shown in FIGS. 9 and 10), an absolute value of a difference between a HOMO energy level of the second optical adjustment layer 5 and a HOMO energy level of the hole transport layer 7 is less than 0.5 eV, an absolute value of a difference between a LUMO energy level of the second optical adjustment layer 5 and a LUMO energy level of the hole transport layer 7 is greater than 1 eV, and the first optical adjustment layer 5 also serves as a hole block layer.

In some embodiments, at least a part of a surface of the optical adjustment layer 5 away from the quantum dot light emitting layer 3 is convex or concave; and/or at least a part of a surface of the optical adjustment layer 5 close to the quantum dot light emitting layer 3 is convex or concave. This design is favorable to improving the light extraction performance of the surface of the optical adjustment layer 5, and is favorable to improving the light extraction efficiency of the quantum dot light emitting diode.

It should be noted that, while the first electrode 1 serves as an anode and the second electrode 2 serves as a cathode, the first electrode 1 is a transparent electrode, and the second electrode 2 is a reflective electrode. In this case, the quantum dot light emitting diode is a normal bottom emission type quantum dot light emitting diode; and in this case, the material of the first electrode 1 may be a metal oxide material, and the material of the second electrode 2 may be a metal material. Where the material of the first electrode 1 is a metal oxide material (for example, ITO), the metal oxide electrode 9 for matching work function is not required to be arranged on a side of the first electrode 1 away from the base substrate 6.

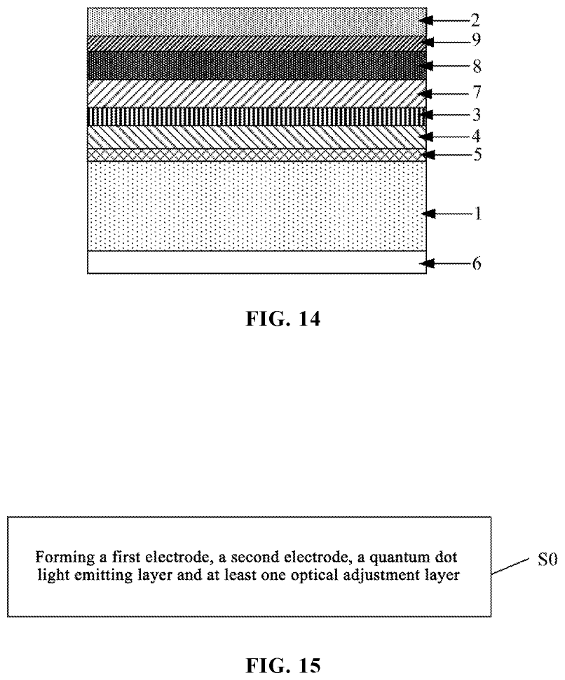

FIG. 14 is a schematic cross-sectional view of another quantum dot light emitting diode according to an embodiment of the present disclosure. As shown in FIG. 14, unlike the previous embodiments, the quantum dot light emitting diode shown in FIG. 14 has the first electrode 1 as a cathode and the second electrode 2 as an anode. In this case, the electron transport layer 4 is located on a side of the quantum dot light emitting layer 3 close to the base substrate 6, and the hole transport layer 7 and the hole injection layer 8 are located on a side of the quantum dot light emitting layer 3 away from the base substrate 6.

In some embodiments, the first electrode 1 in FIG. 14 is a reflective electrode, and the second electrode 2 in FIG. 14 is a transflective electrode. That is, the quantum dot light emitting diode is an inverted top emission type quantum dot diode.

In other embodiments, the first electrode 1 in FIG. 14 is a transparent electrode, and the second electrode 2 in FIG. 14 is a reflective electrode. That is, the quantum dot light emitting diode is an inverted bottom emission type quantum dot light emitting diode.

Of course, FIG. 14 only exemplarily depicts a case where the quantum dot light emitting diode includes an optical adjustment layer 5, and the optical adjustment layer 5 is located between the first electrode 1 and the quantum dot light emitting layer 3, which case only serves as an example, and does not limit the technical solution of the present disclosure.

In the embodiment of the present disclosure, the quantum dot light emitting diode may be any of a normal top emission type quantum dot light emitting diode, a normal bottom emission type quantum dot light emitting diode, an inverted top emission type quantum dot light emitting diode, and an inverted bottom emission type quantum dot light emitting diode. The number of the optical adjustment layers 5 arranged in the quantum dot light emitting diode is not limited, and may be, for example, one, two, or more. Meanwhile, the position of the optical adjustment layer 5 in the quantum dot light emitting diode is not limited, and may be any position between the first electrode 1 and the second electrode 2, as long as the optical adjustment layer 5 is ensured not to be adjacent to the reflective electrode.

In addition, where the quantum dot light emitting diode is a top emission quantum dot light emitting diode (the first electrode 1 is a reflective electrode, and the second electrode 2 is a transparent electrode or a transflective electrode), a light extracting layer (capping layer) may be arranged on a side of the second electrode 2 away from the base substrate 6, to improve the light extraction efficiency of the quantum dot light emitting diode. This case is not given a corresponding figure.

Based on the same inventive concept, an embodiment of the present disclosure further provides a method of manufacturing a quantum dot light emitting diode. FIG. 15 is a flowchart of a method of manufacturing a quantum dot light emitting diode according to an embodiment of the present disclosure. As shown in FIG. 15, the manufacturing method includes the following step S0.

Step S0, forming a first electrode, a second electrode, a quantum dot light emitting layer and at least one optical adjustment layer.

The quantum dot light emitting layer is located between the first electrode and the second electrode, one of the first electrode and the second electrode is a reflective electrode, the other one of the first electrode and the second electrode is a transmissive electrode or a transflective electrode, the optical adjustment layer is located between the first electrode and the second electrode, and the optical adjustment layer is configured to form a microcavity structure with the reflective electrode, so that the light extraction efficiency P of the quantum dot light emitting diode satisfies 25%≤P≤98%.

In some embodiments, the optical adjustment layer is formed through an evaporation process, a spin coating process, or a printing process. In practical applications, the specific process for forming the optical adjustment layer may be selected according to the material of the optical adjustment layer, which is not limited by the present disclosure. As an alternative embodiment, the optical adjustment layer may be formed through spin coating a nanosheet material, and the nanosheet can effectively enhance the light extraction performance of the optical adjustment layer in a vertical direction.

Further, where dielectric layers such as an electron injection layer, a hole injection layer, and a hole transport layer are arranged in the quantum dot light emitting diode, the step S0 further includes the steps of forming the electron injection layer, forming the hole injection layer, and forming the hole transport layer.

Based on the same inventive concept, an embodiment of the present disclosure further provides a display panel, where the display panel includes the quantum dot light emitting diode according to any of the foregoing embodiments, and the quantum dot light emitting diode may be formed by the manufacturing method described above. The detailed description of the quantum dot light emitting diode in the display panel and the manufacturing method thereof may refer to the corresponding contents in the foregoing embodiments, which is not repeated herein.

In some embodiments, to realize a color display of the display panel, the display panel includes a first quantum dot light emitting diode emitting blue light and a second quantum dot light emitting diode emitting light of other colors, where at least the first quantum dot light emitting diode is the quantum dot light emitting diode. The number of the microcavity structures in the first quantum dot light emitting diode is greater than that of the microcavity structures in the second quantum dot light emitting diode.

The light of other colors may be at least one of red light, green light, cyan light, magenta light, and yellow light. As an example, the display panel includes a blue quantum dot light emitting diode (a first quantum dot light emitting diode) emitting blue light, a red quantum dot light emitting diode (a second quantum dot light emitting diode) emitting red light, and a green quantum dot light emitting diode (a second quantum dot light emitting diode) emitting green light.

The optical adjustment layer may be arranged in the blue quantum dot light emitting diode only, and is not included in the red quantum dot light emitting diode or the green quantum dot light emitting diode, so that the number of microcavity structures in the blue quantum dot light emitting diode is greater than that in the red quantum dot light emitting diode or the green quantum dot light emitting diode. Alternatively, all of the blue quantum dot light emitting diode, the red quantum dot light emitting diode and the green quantum dot light emitting diode are each provided with an optical adjustment layer, but the number of the optical adjustment layers in the blue quantum dot light emitting diode is greater than the number of optical adjustment layers in the red quantum dot light emitting diode or the green quantum dot light emitting diode.

In the embodiment of the present disclosure, it is preferable that the optical adjustment layer is arranged in the blue quantum dot light emitting diode, this is because it is obtained through an experiment simulation that after the optical adjustment layer is arranged in the blue quantum dot light emitting diode, the light extraction efficiency of the blue quantum dot light emitting diode can be significantly improved, and the light extraction efficiency of the blue quantum dot light emitting diode can reach a level of not less than 25%.

Where the optical adjustment layers are arranged in the red quantum dot light emitting diode and the green quantum dot light emitting diode, it is found from the simulation results that the light extraction efficiencies of the red quantum dot light emitting diode and the green quantum dot light emitting diode are improved a bit compared with the case where the optical adjustment layers are not included, but the improvement effect of the light extraction efficiencies are not obvious compared with the blue quantum dot light emitting diode provided with the optical adjustment layer.

The display panel according to the embodiment of the present disclosure may be applied to a display apparatus, and the display apparatus may be any product or component with a display function, such as a television, a digital camera, a mobile phone, a tablet computer, or the like.

It will be understood that the above embodiments are merely exemplary embodiments adopted to illustrate the principles of the present disclosure, and the present disclosure is not limited thereto. It will be apparent to one of ordinary skill in the art that various modifications and improvements can be made without departing from the spirit and essence of the present disclosure, and such modifications and improvements are also considered to be within the protection scope of the present disclosure.

1. A quantum dot light emitting diode, comprising a first electrode, a second electrode and a quantum dot light emitting layer between the first electrode and the second electrode, wherein one of the first electrode and the second electrode is a reflective electrode, and the other of the first electrode and the second electrode is a transmissive electrode or a transflective electrode; and
at least one optical adjustment layer is between the first electrode and the second electrode, each of the at least one optical adjustment layer is configured to form a microcavity structure with the reflective electrode, such that a light extraction efficiency P of the quantum dot light emitting diode satisfies 25%≤P≤98%.

2. The quantum dot light emitting diode according to claim 1, wherein a transmittance Q of the optical adjustment layer satisfies 70%≤Q<100%; and
a reflectivity R of the optical adjustment layer satisfies 0<R≤30%.

3. The quantum dot light emitting diode according to claim 1, wherein a thickness of the optical adjustment layer is in a range of 1 nm to 35 nm.

4. The quantum dot light emitting diode according to claim 1, wherein a refractive index of the optical adjustment layer is in a range of 0.1 to 0.3.

5. The quantum dot light emitting diode according to claim 1, wherein a material of the optical adjustment layer comprises a semiconductor material or a metal material.

6. The quantum dot light emitting diode according to claim 5, wherein the material of the optical adjustment layer comprises the metal material, and the optical adjustment layer is not in direct contact with the quantum dot light emitting diode.

7. The quantum dot light emitting diode according to claim 1, further comprising at least one functional dielectric layer between the optical adjustment layer and the reflective electrode, which satisfies:
$$\vert {ϕ}_{1} \vert + \vert {ϕ}_{2} \vert + \frac{2 π}{λ} {\sum }_{i = 1}^{k} 2 {n}_{i} {d}_{i} = {m}_{1} * 2 π$$
wherein Φ₁ represents a phase shift generated by reflection of light on the reflective electrode, Φ₂ represents a phase shift generated by reflection of light on the optical adjustment layer, k represents the number of the at least one functional dielectric layer between the optical adjustment layer and the reflective electrode, nᵢ and dᵢ represent a refractive index and a thickness of an i^{th} functional dielectric layer close to the reflective electrode, respectively, m₁ is a preset positive integer, λ represents an emission peak wavelength of the quantum dot light emitting layer, and i is an integer and 1≤i≤k.

8. The quantum dot light emitting diode according to claim 5, wherein
one of the first electrode and the second electrode is the reflective electrode and the other of the first electrode and the second electrode is the transflective electrode;
the at least one functional dielectric layer between the transflective electrode and the reflective electrode satisfies:
$$\vert {ϕ}_{1} \vert + \vert {ϕ}_{3} \vert + \frac{2 π}{λ} {\sum }_{j = 1}^{s} 2 {n}_{j} {d}_{j} = {m}_{2} * 2 π$$
wherein Φ₃ represents a phase shift generated by reflection of light on the transflective electrode, s represents the number of the at least one functional dielectric layer between the transflective electrode and the reflective electrode, nⱼ and dⱼ represent a refractive index and a thickness of an j^{th} functional dielectric layer close to the reflective electrode, respectively, m₂ is a preset positive integer and m₂>m₁, and j is an integer and 1≤j≤s.

9. The quantum dot light emitting diode according to claim 1, wherein one of the first electrode and the second electrode serves as a cathode of the quantum dot light emitting diode, and the other of the first electrode and the second electrode serves as an anode of the quantum dot light emitting diode;
an electron transport layer is between the cathode and the quantum dot light emitting layer; and
a hole injection layer and a hole transport layer are between the anode and the quantum dot light emitting layer.

10. The quantum dot light emitting diode according to claim 9, wherein the at least one optical adjustment layer comprises a first optical adjustment layer, a material of the first optical adjustment layer comprises a semiconductor material; and
the first optical adjustment layer is between the anode and the quantum dot light emitting layer, and an absolute value of a difference between a HOMO energy level of the first optical adjustment layer and a HOMO energy level of the hole transport layer is greater than 1 eV.

11. The quantum dot light emitting diode according to claim 9, wherein the at least one optical adjustment layer comprises a second optical adjustment layer, a material of the second optical adjustment layer comprises a semiconductor material; and
the second optical adjustment layer is between the cathode and the quantum dot light emitting layer, an absolute value of a difference between a HOMO energy level of the second optical adjustment layer and a HOMO energy level of the hole transport layer is less than 0.5 eV, and an absolute value of a difference between a LUMO energy level of the second optical adjustment layer and a LUMO energy level of the hole transport layer is greater than 1 eV.

12. The quantum dot light emitting diode according to claim 1, wherein at least a part of a surface of the optical adjustment layer away from the quantum dot light emitting layer is convex or concave;
and/or at least a part of a surface of the optical adjustment layer close to the quantum dot light emitting layer is convex or concave.

13. The quantum dot light emitting diode according to claim 1, further comprising a base substrate, wherein the first electrode is on the base substrate, and the second electrode is on a side of the first electrode away from the base substrate; and
the first electrode is the reflective electrode, the second electrode is the transflective electrode, and the reflective electrode and the transflective electrode form a microcavity structure;
or, the first electrode is the transmissive electrode, and the second electrode is the reflective electrode.

14. The quantum dot light emitting diode according to claim 13, wherein the reflective electrode serves as an anode of the quantum dot light emitting diode, and a material of the reflective electrode comprises a metal material; and
a metal oxide electrode adjacent to the reflective electrode is on a side of the reflective electrode close to the quantum dot light emitting layer.

15. A display panel, comprising the quantum dot light emitting diode according to claim 1.

16. The display panel according to claim 15, wherein the display panel comprises a first quantum dot light emitting diode emitting blue light and a second quantum dot light emitting diode emitting light of another color, wherein at least the first quantum dot light emitting diode is the quantum dot light emitting diode; and
the number of the microcavity structures in the first quantum dot light emitting diode is greater than the number of the microcavity structures in the second quantum dot light emitting diode.

17. A method of manufacturing the quantum dot light emitting diode according to claim 1, comprising:
forming the first electrode, the second electrode, the quantum dot light emitting layer and the at least one optical adjustment layer, wherein the quantum dot light emitting layer is between the first electrode and the second electrode, one of the first electrode and the second electrode is a reflective electrode, and the other of the first electrode and the second electrode is a transmissive electrode or a transflective electrode; each of the at least one optical adjustment layer is configured to form a microcavity structure with the reflective electrode, such that the light extraction efficiency P of the quantum dot light emitting diode satisfies 25%≤P≤98%.

18. The method according to claim 17, wherein the optical adjustment layer is formed through an evaporation process, a spin coating process, or a printing process.

19. The display panel according to claim 15, wherein a transmittance Q of the optical adjustment layer satisfies 70%≤Q<100%; and
a reflectivity R of the optical adjustment layer satisfies 0<R≤30%.

20. The display panel according to claim 15, wherein a thickness of the optical adjustment layer is in a range of 1 nm to 35 nm.
